(19) United States
(12) Patent Application Publication
(10) Pub. No.: US 2004/0164366 A1
(43) Pub. Date: Aug. 26, 2004

(54) Microelectronic device and method of its manufacture

(76) Inventors: William Lane, County Cork (IE); Paul Lambkin, County Cork (IE)

Correspondence Address: VAN DYKE, GARDNER, LINN AND BURKHART, LLP, 2851 CHARLEVOIX DRIVE, S.E., P.O. BOX 888695, GRAND RAPIDS, MI, 49588-8695, US

(21) Appl. No.: 10/480,606

(22) PCT Filed: Jun. 5, 2002
(86) PCT No.: PCT/IE02/00073

(30) Foreign Application Priority Data
Jun. 11, 2001 (IE) S010552

(51) Int. Cl. H01L 21/00; H01L 27/14; H01L 29/82; H01L 31/058

(52) U.S. Cl. 257/414; 438/48; 257/467; 438/54

(57) ABSTRACT

A method of fabricating a reference microbolometer structure on a substrate comprises the steps of applying a sacrificial layer to the substrate; applying a further layer to the sacrificial layer, the further layer incorporating a temperature sensitive material; and partially removing the sacrificial layer from the substrate such that a portion of the sacrificial layer is not removed at least in a region between temperature sensitive material and the substrate. The portion of the sacrificial layer that is not removed thereby forms a body of solid material, and a path of low thermal impedance, between the temperature sensitive material and the substrate.

This invention relates to a microelectronic device and method of its manufacture. In particular, it relates to a microbolometer, and more particularly to a reference microbolometer.

A bolometer is a thermally isolated structure, which has an electrical property such as resistance that is temperature-dependent. Infrared radiation impinging upon the structure will be absorbed, causing its temperature to rise. The consequent change in resistance can be detected electrically, whereby a measure of the temperature of the bolometer can be determined. Microbolometers, to which this invention relates, are bolometers implemented using microelectronic construction techniques. Microbolometers have many applications. For example, an imaging array can be constructed of multiple microbolometers, which can be used, for example, to capture a thermal image of a scene. Such an array has multiple applications including night-vision apparatus, apparatus for viewing in adverse conditions, such as in the presence of smoke, in apparatus for detection of hot components in apparatus, amongst many others.

High-sensitivity measurement of the temperature changes caused by IR radiation requires the comparative measurement of the resistance of two microbolometers, one of which has high thermal sensitivity and the other which has low thermal sensitivity. The low thermal sensitivity bolometer (referred to as the “reference microbolometer”) must be well matched in resistance value to the bolometer of high thermal sensitivity (referred to as the “sensitive microbolometer”) at some arbitrary temperature, usually an appropriate ambient temperature.

It is common to construct a microbolometer having temperature sensitive resistive material carried on a bridge structure that is spaced from a substrate in order that the sensitive material is thermally isolated from the substrate. This allows the temperature of the microbolometer to change in dependence upon the infrared radiation impinging upon it, while the substrate itself remains at ambient temperature. The spacing between the bridge structure and the substrate is typically in the order of a few μm (e.g. between 1.5 and 6 μm). However, other fabrication technologies are being used to build IR sensing structures and so it is envisaged that spacing in the range of 0.5 to 100 μm could be employed.

On the other hand, it is advantageous to ensure that sensitive material of a reference microbolometer is in good thermal contact with the substrate to ensure that it remains close to ambient temperature. A straightforward method of constructing a reference microbolometer would be to place it on top of the field region of the substrate, without any table under it, to minimise the thermal impedance to ground. However, if such a reference microbolometer is to be constructed in association with a raised table sensitive microbolometer, the step height difference between the sensitive microbolometer and the reference device causes difficulties during fabrication. In advanced VLSI process technologies, the patterning of the different layers is done using photolithography equipment, which has very limited depth of focus that cannot tolerate height differences. Thus, either a large pattern mismatch between the two bolometers must be tolerated, or an extra mask level is required. The extra mask will somewhat improve the matching, but is still not ideal since it is easy to accidentally introduce fixed offsets in pattern linewidth (and thus bolometer value matching) and it increases process cost.

An aim of this invention is to provide a structure for a reference microbolometer, and a method of making such a structure, that overcomes or at least ameliorates these difficulties.

Accordingly, from a first aspect, the invention provides a microbolometer structure formed on a substrate comprising a bridge structure over the substrate, the bridge structure incorporating a temperature sensitive material, in which at least part of a region between the bridge and the substrate is occupied by a solid material that acts as a thermally conductive pathway between the bridge and the substrate.

Such a structure can be arranged to minimise the difference in height between the reference microbolometer and an adjacent sensitive microbolometer, thereby overcoming or reducing problems arising from the presence of structures of different heights on the substrate, so obviating the need to introduce an additional mask layer.

While not limiting the scope of the invention, the properties of the solid material can be summarised usefully as follows:

good thermal conductor;

stable under processing conditions, e.g. no gas evolution; and

electrical non-conductor, i.e. a dielectric, or at least processed in a way which denies a current carrying path to another conductor that might run under the table (e.g. covering the conducting solid material with an insulator to ensure now conduction takes place).

The solid material is normally disposed to ensure that the temperature sensitive material of the reference microbolometer has a satisfactory thermal path to the substrate to perform as a reference microbolometer. Another criterion of great value is to try and match the thermal mass of the reference device to that of the sensing device. Scaling the sizes of the reference and sensing bolometers in proportion to their relative thermal masses can accomplish this. The reference bolometer will have an apparently larger thermal mass due to its “solid material” short to the substrate; this can be compensated for by careful geometric design of the reference and sensing structures.

The sensitive material may be integral with the bridge structure, or may be carried on it as a separately formed element. In the latter case, the sensitive material may be disposed on the bridge structure between it and the substrate, or on the bridge structure on a surface remote from the substrate.

Typically, in a microbolometer embodying the invention, the thickness of the solid material is several μm. For example, it may be approximately 1, 2, 3, 4 or 5 μm. The sensitive material, most typically, has an electrical resistance that changes with temperature. For example, it may be a metal such as titanium metal. This may have a resistance of approximately 3.3 Ω/sq. Most typically, the sensitive material will be disposed in a meander on the bridge structure. However, it is quite common with sensing films other than Titanium to make the whole table the sensing element with an arbitrary geometry (usually squarish), as the resistance of the bolometer is high enough without using a meander. Also the sensing element need not be a resistor, there are examples of sensing elements which use a pyroelectric effect to give a change in capacitance or similar.

In preferred embodiments, the solid material is entirely enclosed within a void formed between the bridge structure and the substrate. The void is advantageously sealed against the passage of fluid, typically gas, into or out of the void. As will be seen from the discussions below, this configuration can assist in a construction process for the structure. Most advantageously, the solid material substantially entirely fills the void. The presence of other material, gas in particular, could lead to destruction of the structure whilst undergoing heat treatment during its construction.

The solid material may be a material used as a sacrificial component during construction of structures on the substrate. As a particular example, it may be a material used in the construction of a bridge structure on the substrate, most especially, a bridge structure of a sensitive microbolometer. For example, the solid material may be a polymer such as polyimide.

From second aspect, the invention provides, in combination, a reference microbolometer being in accordance with the first aspect of the invention and a sensitive microbolometer constructed on a common substrate, the sensitive microbolometer having a bridge structure that incorporates a temperature sensing material, in which the bridge structure of the reference microbolometer and the bridge structure of the sensitive microbolometer being spaced at similar distances from the substrate.

In this context, “similar distances” may mean distances within 1 μm, 0.5 μm or 0.1 μm of one another.

In such a combination, the reference microbolometer and the sensitive microbolometer are typically configured to have a similar electrical resistance at a typical ambient temperature of the substrate.

Most advantageously, the microbolometers of such a combination are constructed in a common fabrication process.

From a third aspect, this invention provides a method of fabricating a reference microbolometer structure on a substrate comprising:

applying a sacrificial layer to the substrate;

applying a further layer to the sacrificial layer, the further layer incorporating a temperature sensitive material; and

partially removing the sacrificial layer from the substrate such that a portion of the sacrificial layer is not removed at least in a region between temperature sensitive material and the substrate.

The portion of the sacrificial layer that is not removed thereby forms a body of solid material, and a path of low thermal impedance, between the temperature sensitive material and the substrate.

In typical embodiments, removal of the sacrificial layer is achieved by exposing the layer to a removal medium, most usually a gas. In such embodiments, prevention of removal of a portion of the sacrificial layer is achieved by isolating that portion from the removal medium. For example, this may be achieved by enclosing the portion of sacrificial material in a void between the substrate and the further layer. Advantageously, the void is substantially entirely filled with sacrificial material.

Furthermore, the further layer may be configured such that, upon removal of the sacrificial layer, a region of the further layer forms a bridge structure spaced from the substrate, at least within the bridge structure, the further layer incorporating temperature sensitive material whereby it can function as a sensitive bolometer.

Temperature sensitive material may be incorporated into the further layer as an integral component of it, or by forming a separate later on it.

An embodiment of the invention will now be described in detail, by way of example, and with reference to the accompanying drawings, in which:

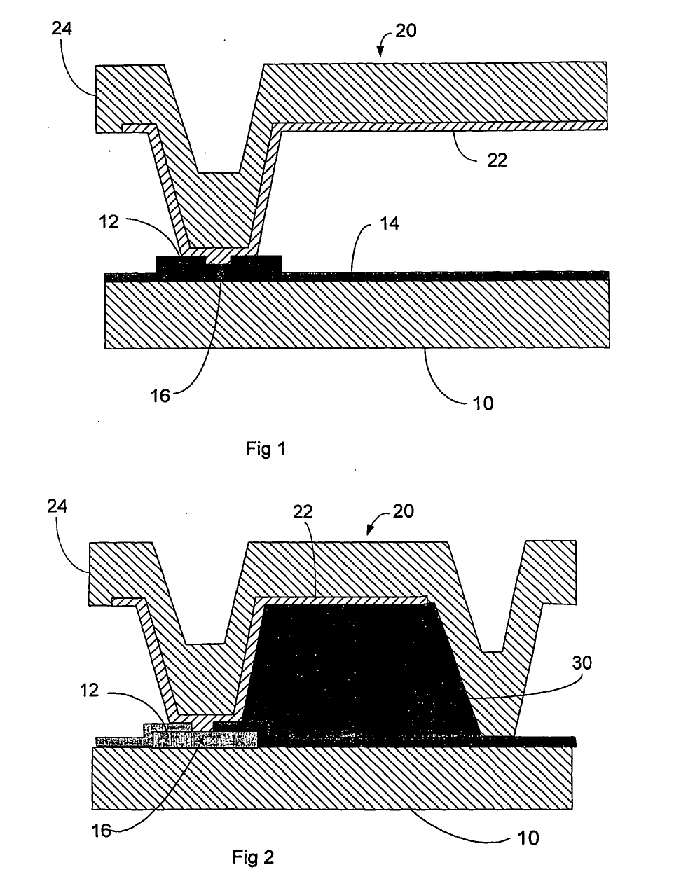

FIG. 1 is a section through a known sensitive microbolometer structure;

FIG. 2 is a section through a reference microbolometer structure being an embodiment of the invention; and

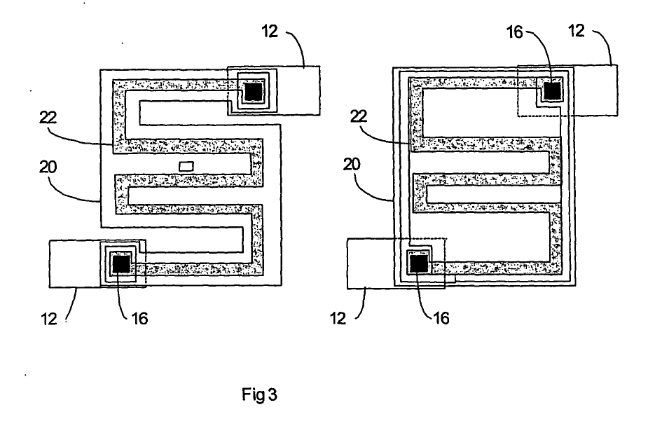

FIG. 3 is a plan view of a structure including a sensitive microbolometer and a reference microbolometer embodying the invention.

With reference first to FIG. 1, a known sensitive microbolometer is constructed on a substrate 10. (A substrate in this context is typically but not exclusively a semiconductor wafer incorporating layers of semiconducting and other materials, on top of which are isolating dielectric layers interspersed with a number of insulated metal layers, usually but not exclusively part of a CMOS or other IC processed wafer.) This structure will now be described briefly. An upper surface of the substrate 10 carries metal conductors 12. A passivation layer 14 is formed on the upper surface of the substrate 10 to cover the surface and the conductors 12. Contact vias 16 are formed through the passivation layer, as required.

A bridge structure 20 is formed above the upper surface of the substrate 10 as part of a layer 24 of thermally absorptive oxide. A lower surface of the bridge structure 20 carries a thermally sensitive electrical resistive element 22 formed of titanium metal. The bridge structure 20 is formed with a land portion that is spaced from the substrate 10 by several μm and a leg portion that extends towards and is carried on the substrate 10. The leg region may make contact with the substrate 10 in the region of a via in order that the resistive element 22 can make electrical contact with a conductor 12.

The region between the land portion of the bridge 20 and the substrate is empty (that is to say, it contains nothing other than air, or more typically a vacuum) whereby the land region is, to a great extent, thermally insulated from the substrate.

With reference now to FIG. 2, a reference microbolometer embodying the invention is constructed on a substrate 10. The reference microbolometer has structure in common with the sensitive microbolometer described above. As with the sensitive microbolometer, an upper surface of the substrate 10 carries metal conductors 12. A passivation layer 14 is formed on the upper surface of the substrate 10 to cover the surface and the conductors 12. Contact vias 16 are formed through the passivation layer, as required.

A bridge structure 20 is formed above the upper surface of the substrate 10 as part of a layer 24 of thermally absorptive oxide. A lower surface of the bridge structure 20 carries a thermally sensitive electrical resistive element 22 formed of titanium metal. The bridge structure 20 is formed with a land portion that is spaced from the substrate 10 by several μm and a leg portion that extends towards and is carried on the substrate 10. The leg region may make contact with the substrate 10 in the region of a via in order that the resistive element 22 can make electrical contact with a conductor 12.

In this embodiment of the invention, the region between the land portion of the bridge 20 and the substrate is filled with a body of solid material 30. The solid material acts as a thermal conductor to act as a low-impedance path for heat between the bridge structure 20 and the substrate 10, thereby maintaining the temperature of the bridge structure, and the sensitive element 22 carried on it, close to the temperature of the substrate 10. In this embodiment, the solid material 30 is polyimide, being a remainder from a 1-2 μm layer of sacrificial polyimide which has, in other regions of the substrate, been removed by an ashing process.

In both cases, the thermally absorptive layer 24 is formed of a material that is absorptive to infrared radiation of a wavelength that the microbolometer is intended to detect.

Construction of the reference microbolometer embodying the invention will now be described in further detail.

The description of the fabrication process can best be described by way of a fabrication “run card”, as presented below:

| Step Number | General | Specific |
|---|---|---|
| 1. Starting | Fully processed CMOS wafer | |
| Material | up to the point to which | |
| | BPSG has been deposited and | |
| | the back of the wafer has | |
| | been stripped. | |
| 2. Contact | Contact vias are opened in the | BPSG 7500-8000 Å |
| definition. | BPSG to gate poly. | |
| 3. Pre-metal | Pre-metal clean | 10:1 HF for 30 s |
| clean | | |
| 4. Metal 1 | Deposit and pattern metal 1. | 5000 Å Al/1% Si |
| | | 60-70 mΩ/Sq |
| 5. Passivation. | Deposit and pattern nitride | 2000 Å plasma-enhanced |
| | passivation. | chemical vapour |
| | | deposition nitride |
| 6. Sacrificial | Deposit and pattern polymer | Polyimide is spin |
| Layer. | sacrificial layer. Vias are cut | deposited and cured. |
| | in the sacrificial layer down | The details of |
| | which the microbolometer | this process are available. |
| | metal and ‘table leg’ will run. | The polyimide thickness |
| | The thickness of the | after cure is 30500 Å. It |
| | sacrificial layer need not be | is important that a |
| | critically controlled since the | photoresist stripper such |
| | structure is not designed to | as EKC is used to |
| | be optically resonant. | remove all resist layers |
| | | subsequent to |
| | | polyimide deposition. A |
| | | reduction in polyimide |
| | | thickness can be tolerated |
| | | during etching. |
| 7. Bolometer | Deposit and pattern | Sputter 2000 Å Ti metal. |
| Metal | bolometer resistor metal. | 3.3 Ω/sq. Ti is plasma |
| | | etched. |
| 8. Bolometer | Deposit and pattern dielectric | Deposit and pattern, strip |
| support/ | table/support structure. This | 1 μm of oxide. |
| absorber. | support structure must be an | |
| | IR absorber at the wavelength | |
| | of interest. The table | |
| | thickness is not critical above | |
| | a certain material dependent | |
| | minimum value. | |
| 9. Remove | Polymer sacrificial layer is | Polyimide is ashed for 12 |
| sacrificial | removed by ‘ashing’. | minutes thus releasing |
| layer | | the oxide table |
| | | structures. |
| 10. RTA | Rapid Thermal Anneal | RTA 400° C. for 30 s. |
| | | This important step |
| | | preserves the elevated |
| | | value of the temperature |
| | | coefficient of |
| | | resistance of the Ti. |

In the above process, the polyimide layer acts as a sacrificial layer that is, for the most part, removed during the ashing process by application of suitable ashing gases. However, the patterning mask is drawn such that the polyimide in the region below the bridge is not removed, and is instead left as a body of solid material 30 in the completed structure. This is achieved by ensuring that the polyimide sacrificial layer is fully surrounded by the absorbing oxide layer 24 in step 8 above during the course of polyimide ashing and removal in step 9 above. The absorbing oxide layer 24 is arranged to be in contact with the substrate 10 (or layers 12, 14 formed on the substrate 10) to completely enclose a region of the polyimide layer. This has the effect of preventing the ashing gas reaching the polyimide layer, thereby preventing its removal. There must be no holes formed in the covering region of the absorbing oxide layer 24 that would allow ingress of the ashing gases.

It is important that the polyimide layer be fully cured prior to application of the absorbing oxide layer 24. Otherwise, outgassing from the polyimide sealed beneath the absorbing oxide layer 24 might cause a build-up of pressure that could result in damage to or destruction of the structure.

One issue that must be considered in relation to performance of a reference microbolometer embodying the invention is that there may be greater thermal impedance between the resistive element 22 and the substrate 10 than would be the case if the resistive element was in close contact with the substrate. However, this has been found not to be a significant penalty in practice. With this in mind, it should be noted that the thickness of the solid body 30 of polyimide (typically 1-5 μm) is much less than the width or length of the table 20 in a typical microbolometer application (typically 40-100 μm). The thermal conductivity of polyimide, at ˜25 W/cm-K, compares very favourably to that of silicon dioxide at 0.014 W/cm-K and silicon at 1.4 W/cm-K. This shows that the additional thermal resistance contribution of the solid body 30 is small.

It will be appreciated that the above-described structure can be very advantageously fabricated on a common substrate with a sensitive microbolometer, as shown in FIG. 3. In the case of the sensitive microbolometer, the oxide layer in the region of the bridge structure 20 does not fully enclose the sacrificial layer. This allows the ashing gasses to come into contact with the polyimide layer in the region of the bridge structure, thereby removing the polyimide layer to leave an unfilled space between the substrate 10 and the bridge structure 20. It will be seen that such a sensitive microbolometer can readily be constructed in a common fabrication process on a common substrate with a reference microbolometer as described above since the two types of microbolometer differ in the structure of the absorptive oxide layer 24. (Naturally, in practice, many of each type of microbolometer will be formed on each substrate.) It will also be seen that the relative heights of these two types of microbolometer will be similar, thereby ensuring that both structures can be formed with a single, well focused mask image.

1. A microbolometer structure formed on a substrate comprising a bridge structure over the substrate, the bridge structure incorporating a temperature sensitive material, in which at least part of a region between the bridge and the substrate is occupied by a solid material that acts as a thermally conductive pathway between the bridge and the substrate.

2. A microbolometer structure according to claim 1 in which the solid material is disposed to ensure that the sensitive material of the reference microbolometer has a satisfactory thermal path to the substrate.

3. A microbolometer structure according to claim 1 or claim 2 in which the sensitive material is integral with the bridge structure.

4. A microbolometer structure according to claim 1 or claim 2 in which the sensitive material is carried on the bridge structure as a separately formed element.

5. A microbolometer structure according to claim 4 in which the sensitive material may be disposed on the bridge structure between it and the substrate, or on the bridge structure on a surface remote from the substrate.

6. A microbolometer structure according to any preceding claim in which the solid material has a thickness of several am.

7. A microbolometer structure according to claim 6 in which the solid material has a thickness of one of approximately 1, 2, 3, 4 or 5 μm.

8. A microbolometer according to any preceding claim in which the sensitive material has an electrical resistance or other heat sensing property that changes with temperature.

9. A microbolometer according to claim 8 in which the sensitive material is titanium metal.

10. A microbolometer according to any preceding claim in which the sensing material is disposed in a meander on the bridge structure.

11. A microbolometer according to any preceding claim in which solid material is entirely enclosed within a void formed between the bridge structure and the substrate.

12. A microbolometer according to claim 11 in which the void is sealed against the passage of fluid into or out of the void.

13. A microbolometer according to any preceding claim in which in which the solid material substantially entirely fills the void.

14. A microbolometer according to any preceding claim in which the solid material is a material used as a sacrificial component during construction of structures on the substrate.

15. A microbolometer according to claim 13 or claim 14 in which the solid material is a material used in the construction of a bridge structure on the substrate

16. A microbolometer according to claim 15 in which the solid material is a material used in the construction of a bridge structure of a sensitive microbolometer.

17. A microbolometer according to any preceding claim in which the solid material is polyimide.

18. A microbolometer structure formed on a substrate substantially as herein described with reference to the accompanying drawings.

19. A microbolometer combination including a reference microbolometer in accordance with any preceding claim and a sensitive microbolometer constructed on a common substrate, the sensitive microbolometer having a bridge structure that incorporates a temperature sensing material, in which the bridge structure of the reference microbolometer and the bridge structure of the sensitive microbolometer being spaced at similar distances from the substrate.

20. A microbolometer combination according to claim 19 in which the bridge structure of the reference microbolometer and the bridge structure of the sensitive microbolometer are spaced at distances within 1 μm, 0.5 μm or 0.1 μm of one another.

21. A microbolometer combination according to claim 19 or claim 20 in which the reference microbolometer and the sensitive microbolometer are configured to have a similar electrical resistance at a typical ambient temperature of the substrate.

22. A microbolometer combination according to any one of claims 19 to 21 in which the microbolometers of such a combination are constructed in a common fabrication process.

23. A method of fabricating a reference microbolometer structure on a substrate comprising:
applying a sacrificial layer to the substrate;
applying a further layer to the sacrificial layer, the further layer incorporating a temperature sensitive material; and
partially removing the sacrificial layer from the substrate such that a portion of the sacrificial layer is not removed at least in a region between temperature sensitive material and the substrate.

24. A method according to claim 23 in which removal of the sacrificial layer is achieved by exposing the layer to a removal medium.

25. A method according to claim 24 in which the removal medium is a gas.

26. A method according to claim 24 or claim 25 in which prevention of removal of a portion of the sacrificial layer is achieved by isolating that portion from the removal medium.

27. A method according to claim 26 in which isolation of a portion of sacrificial material is achieved by enclosing the portion of sacrificial material in a void between the substrate and the further layer.

28. A method according to claim 27 in which the void is substantially entirely filled with sacrificial material.

29. A method according to any one of claims 23 to 28 in which the further layer is configured such that, upon removal of the sacrificial layer, a region of the further layer forms a bridge structure spaced from the substrate, at least within the bridge structure, the further layer incorporating temperature sensitive material whereby it can function as a sensitive bolometer.

30. A method according to any one of claims 23 to 29 in which sensitive material is incorporated into the further layer as an integral component of it, or by forming a separate layer on it.

31. A reference microbolometer substantially as described herein with reference to FIGS. 2 and 3 of the accompanying drawings.

32. A microbolometer combination substantially as described herein with reference to the accompanying drawings.

33. A method of fabricating a reference microbolometer structure on a substrate substantially as described herein with reference to the accompanying drawings.
